(19) United States
(12) Patent Application Publication
(10) Pub. No.: US 2013/0092210 A1
(43) Pub. Date: Apr. 18, 2013

(54) LIGHT AND CARRIER COLLECTION MANAGEMENT PHOTOVOLTAIC STRUCTURES

(71) Applicants: Stephen J. Fonash, State College, PA (US); Wook Jun Nam, State College, PA (US)

(72) Inventors: Stephen J. Fonash, State College, PA (US); Wook Jun Nam, State College, PA (US)

(73) Assignee: SOLARITY, INC., State College, PA (US)

(21) Appl. No.: 13/806,591

(22) PCT Filed: Jun. 23, 2011
(86) PCT No.: PCT/US11/41698

§ 371 Date: Dec. 21, 2012

Related U.S. Application Data
(60) Provisional application No. 61/357,738, filed on Jun. 23, 2010.

(51) Int. Cl. H01L 31/0224; H01L 31/0352; H01L 31/042

(52) U.S. Cl. CPC H01L 31/022425; H01L 31/042; H01L 31/03529; B82Y 99/00
USPC 136/244; 136/255; 977/948

(57) ABSTRACT

A photovoltaic device is provided that includes a periodic array having a unit cell with a first electrode protrusion of a height H, characteristic width W, and period L. An absorber of nominal thickness T has a volume with a first component between the electrode element protrusions and a second component completely covering the electrode protrusions, H, W, and L for a given T allow carrier collection from the majority of points within the volume and simultaneously to enhance the photon density distribution within the absorber resulting from path length, photonic and plasmonic effects produced by the topology and morphology created by the electrode shapes and the volume distribution between the first and the second components.

### RELAYED APPLICATIONS

This application claims priority benefit of U.S. Provisional Application Ser. No. 61/357,738 filed Jun. 23, 2010; the contents of which are hereby incorporated by reference.

### FIELD OF THE INVENTION

The field of this invention is photovoltaic devices for energy conversion. The invention is specifically directed to the use of the solar spectrum for producing electrical power and therefore concentrates on solar cell photovoltaic devices. The devices of this invention can also be used to convert the solar spectrum into chemical energy (e.g. via photolysis) and for general electromagnetic energy detection applications.

### BACKGROUND OF THE INVENTION

Photovoltaics, the conversion of light energy into electrical energy, has been studied since Becquerel's discovery of photovoltaic action in 1839 (C. Becquerel, Compt. Rend, 9, 561 (18391). By the late 1950's other cell photovoltaic devices were 14% efficient in converting sun light at the earth's surface into electrical power and both space and terrestrial applications began to proliferate (S. Fonash, Solar Cell Device Physics, Elsevier, Hoboken, N.J. (2010)). While the energy conversion efficiency value is a very important number, there are two other factors that must also be evaluated when considering solar cells for terrestrial electrical power production. These are cost per watt of power production capability and device lifetime. While device lifetimes have been generally adequate, cost per Watt, which includes the cell cost and the installation costs (i.e., true costs), has been the factor limiting the use of photovoltaic power production for terrestrial point of use and grid applications. The situation can be quantified by considering the product:

$$\frac{energy conversion efficiency}{true costs} \times lifetime$$

As seen from this product, cell cost is a critical issue. Reducing the cost of photovoltaic devices necessitates (1) reducing device fabrication cost and (2) using some combination of less absorber material or less expensive absorber materials. Absorbers are a key concern since they are the material that converts the incoming light into photogenerated carriers (electrons and holes or excitons).

The depth light penetrates into an absorber before it is absorbed is termed the absorption length (L_{abc}) and the distance into an absorber from the electrodes in which photogenerated electrons and holes (or excitons) can be harvested is termed the collection length (L_{c}). There are absorbers with (1) absorption and collection lengths both in the nano-scale, (2) absorption lengths in the micro-scale and collection lengths in the nano-scale, and (3) absorption and collection lengths both in the micro-scale. FIGS. 1(a) and 1(b) show the problems that arise in conventional cell configurations due to the commonly encountered situation of very different values for the absorption and collection lengths. In the arrangement depicted in FIG. 1(a), the absorber has wasted material; i.e., there is a large volume in which absorption and photogeneration occur but collection does not. In FIG. 1(b), the absorber volume has been reduced, thereby eliminating absorber material from which carriers cannot be harvested. However, now some of the light is lost. It can be seen from FIGS. 1(a) and 1(b) that these (absorption length)-(collection length) mismatch issues arise because, in the conventional cell configuration, these lengths are in parallel.

Collection configurations such as those of FIGS. 2-4 have been introduced to address the mismatch problem in a series of patents by Fonash and co-workers: U.S. Pat. Nos. 6,399,177; 6,919,119; 7,341,774; U.S. Application Ser. No. 11/972,491; and PCT/US2008/068446); each of these patents and applications are incorporated herein by reference.

These collection configurations seen in FIGS. 2-4 use a very different electrode arrangement in the solar cell from that found in conventional cells; i.e., they use an approach that wastes neither light nor absorber material because L_{c} and L_{abc} are arranged to be essentially perpendicular to each other. This is accomplished by utilizing protruding electrodes such as wires, tubes, and columns, honeycomb-like electrodes, or fin-like electrodes which penetrate into the absorber as is indicated in FIGS. 2-4, respectively. With this approach of electrode elements penetrating into the absorber to aid collection, electrode element spacing and device thickness can be varied independently and customized to fit the L_{c} and L_{abc} properties of a given absorbing material. This collection approach can also be accomplished by having one set of electrode elements in the absorber and the other electrode on the absorber (FIGS. 2-4) or by incorporating both anode and cathode elements into the volume of the absorbing material. Such lateral collection configurations have the effect of shortening the path that absorption-generated excitons, electrons, or holes must travel in the cell from the site of their creation to be harvested- lateral collection type structures allow photogenerated electron and hole (and/or exciton) collection to occur from different directions to the electrodes. A lateral collection configuration is optionally designed to have the positioning and dimensions needed to aid the photogenerated entity (excitons or electrons and holes) having the greatest difficulty in being collected.

Using the lateral collection approach allows photogenerated electrons and holes (and/or excitons) to be harvested by insuring that all points of photogeneration (absorption and carrier photogeneration} are within a collection distance of electrodes. However, a practical difficulty is encountered in using the lateral collection approach: the absorption length of the absorber (i.e.. absorber thickness) may be large enough to cause technological difficulties in fabricating a penetrating electrode array with elements of long enough length to be able to harvest from the whole absorption volume.

A specific demonstration is provided by amorphous silicon. This material requires a thickness of more than 10,000 nm to fully absorb the AM1.5G solar spectrum, yet the collection length is about 400 nm (S. Fonash, Solar Ceil Device Physics, Elsevier, Hoboken, N.J. (2010)). This mismatch means that lateral collection electrode elements would have to penetrate ˜9,600 nm into an amorphous silicon 10,000 nm thick absorber to give all the absorption possible and all the resulting photogenerated carriers the opportunity to be harvested.

In conventional cell structures, this general problem of requiring thick absorbers to insure full absorption of the incoming spectrum has given rise to various approaches to increasing absorption in a material by light trapping thereby allowing thinner absorber layers. These light management approaches to being able to use thinner absorbers and still attain the required degree of absorption include the use of (1) reflection at the back of the absorber to force light to make multiple passes through the absorber so as to at least double the optical path length), (2) texturing at cell surfaces to cause light to enter or reflect at an angle further increasing optical path length, (3) plasmonics to increase photon densities due to near fields, and (4) photonic structures to increase photon densities (S. Fonash, Solar Cell Device Physics, Elsevier, Hoboken, N.J. (2010).

Recently there have been a number of studies of light management, absorption enhancing approaches based on photonics and plasmonics. Some claim to be based on photonics (Z. Fan et al., Nat. Mater, 8 (2009) 648-653) and others claim to exploit plasmonic effects (R. Biswas, et al., Thirty-fourth Photovoltaic Specialists Conf., Philadelphia, Pa., June 2009). Ferry el al. Appl. Phys. Lett., 95,183503 (2009)) have reported an efficiency increase for an amorphous silicon solar cell structure from 4.5% to 6.2% with the use of what they term a plasmonic back reflector. They attribute the efficiency increase primarily to a 26% increase in short circuit current density.

While the aforementioned cell designs do represent improvements over the original cells, there remain significant losses of potential energy capture. Thus, there is a need for an improved photovoltaic device.

### SUMMARY OF THE INVENTION

A solar cell design is provided that allows the construction of solar cell configurations that simultaneously achieve carrier collection from the full absorber volume and an advantageous distribution of the light (photonic) energy within that volume that allows the use of thinner absorber layers thereby using less materials. An inventive device is synonymously referred to herein as a light and carrier collection management (LCCM) device. An inventive device allows for a larger percentage of up to 100% of the volume of the absorber to be within the collection distance of the electrodes and simultaneously allows for light management capabilities that permit thinner absorber materials. Compared to conventional designs, the present invention offers alone or in combination device attributes of: (1) the ability to shape the absorber volume and electrode element position in that volume thereby giving a greater percentage, up to all of the photogenerated species (electrons and holes and/or excitons) the opportunity to be harvested, (2) the technological capability to construct collection electrode elements that can penetrate the absorber volume as required for collection and for light management, and (3) the, ability to use thinner absorbers due to an advantageous light energy distribution.

A photovoltaic device is provided that includes a periodic array having a unit cell with a first electrode protrusion of a height H, characteristic width W, and period L. An absorber of nominal thickness T has a volume with a first component between the electrode element protrusions and a second component completely covering the electrode protrusions. H, W, and L for a given T allow carrier collection from the majority of points within the volume and simultaneously to enhance the photon density distribution within the absorber resulting from path length, photonic and plasmonic effects produced by the topology and morphology created by the electrode shapes and the volume distribution between the first and the second components.

### BRIEF DESCRIPTION OF THE DRAWINGS

FIGS. 1(a) and (b) are cross-sectional schematics of two prior art solar cells, (a) and (b) with the same absorption length (L) and collection length (L_{c}), The dashed arrows in (a) and (b) indicate the volume of the absorber that generates useful (i.e., collectable) current, (a) Conventional design with planar electrodes (top and bottom dark volumes) and with absorber layer thickness equal to the absorption length but greater than the collection length, (b) Conventional design with planar electrodes (top and bottom dark volumes) and with absorber layer thickness equal to the collection length.

FIG. 2 is a perspective view of columnar-like elements of a prior art electrode penetrating into the absorber allowing lateral collection, where the counter electrode in this case is planar and covers the absorber.

FIG. 3 is a perspective view of honeycomb-like elements of a prior art electrode penetrating into the absorber allowing lateral collection. The counter electrode in this ease is planar and covers the absorber.

FIG. 4 is a perspective view of fin-like elements of a a prior art electrode penetrating into the absorber allowing lateral collection, the counter electrode in this case is planar and covers the absorber.

FIG. 5 are cross-sectional and unit cell views of an inventive LCCM device using protrusions in the absorber. In this figure and in FIGS. 6 and 7 the following exemplary material selections are made: material 2 is a transparent insulative material such as glass (through which the light is entering), material 4 is a transparent conducting material, material 6 is an (optional) doping layer for junction formation, material 8 is the protruding electrode element material, material 10 is the absorber, material 12 is doping material for junction formation, material 14 is a selective contact material, and material 16 is the counter electrode material.

FIG. 6 are cross-sectional and unit cell views of an inventive LCCM device using honeycomb-like protrusions.

FIG. 7 are top and cross-sectional views of an inventive LCCM device using column-like protrusions. This figure also shows the light entry direction choice for FIGS. 5 and 6.

FIG. 8 is a cross-sectional view of an inventive device showing the dimensions H, W, R, and T, along with the spacing L.

FIG. 9(a) is a cross-sectional view of a conventional (planar) device and FIG. 9(b) is a cross-sectional view of a corresponding inventive LCCM device (of the type of FIG. 5) with the same nominal thickness absorber layer as FIG. 9(a).

FIG. 10 is a plot of simulation results comparing absorption in an hydrogenated amorphous silicon (a-Si:H) p i-n planar and in a corresponding inventive LCCM cell.

FIG. 11 is a FESEM micrograph showing the cross-section of an actual device. The cross-section is prepared using focused ion beam milling. The AZO nano-columns had d=150 nm, h=525 nm, and L=1290 nm. This device contained an a-Si:H i-layer (t=320 nm), a p-type layer (13 nm) and an n-type layer (60 nm).

FIG. 12 is a plot of the efficiency for an inventive LCCM device compared to a corresponding conventional (control) planar device made with the same absorber and nominal absorber thickness. The efficiency of the inventive LCCM device is seen to be 45% higher than that of the conventional planar device.

FIGS. 13(a), (b), and (c) are plots for inventive LCCM unit cells (used in the numerical modeling) and the corresponding device cross-sections as a function of L-spacing: (a) Non-overlapping domes (L>L_{touch}), with dimensions and layers labeled, (b) touching domes (L=L_{touch}), and (c) overlapping domes (L<L_{touch}). Layers A-D are defined in Table I for each configuration explored.

FIGS. 14 (a) and (b) are plots for inventive devices: (a) A(λ) results for Configuration 1 for the absorber nano-column height H=500 nm and various L spacings, (b) J_{SC} as a function of L for various values of H 350 nm (filled circles) or 550 nm (filled diamonds). The control A(λ) and J_{SC} are shown for comparison. The curves in FIG. 14(b) are provided to aid in viewing data trends.

FIGS. 15. (a) and (b) are plots for inventive devices: (a) A(λ) results for Configuration 2 for the nano-column height H=550 nm, various spacings L, and a D layer of 30 nm of AZO on Ag. (b) J_{SC} as a function of L for H=550 nm and for D layers of 5 (filled circles) or 30 nm (filled diamonds) of AZO on Ag. The curves in FIG. 15(b) are provided to aid in viewing data trends.

FIGS. 16. (a) A(λ) results for Configuration 3 for the nano-column height H=550 nm, various spacings L, and a C layer of 30 nm of AZO between the columns, and (b) J_{SC} as a function of L for H=550 nm and a C layer of 5 or 30 nm of AZO between the columns.

FIGS. 17. (a) A(λ) results for Configuration 4 for the nano-cone height H=550 nm, various spacings L, and a D layer of 30 nm of AZO on Ag, and (b) J_{SC} as a function of L for H=360 nm or 550 nm and a D layer of 30 nm if AZO on Ag.

FIG. 18 are absorption spectra for an embodiment of the present invention in which nanospheres or a nanowire fishnet serve as the protrusions with the L spacing noted. The figure inset is a cross-sectional view of the device structure.

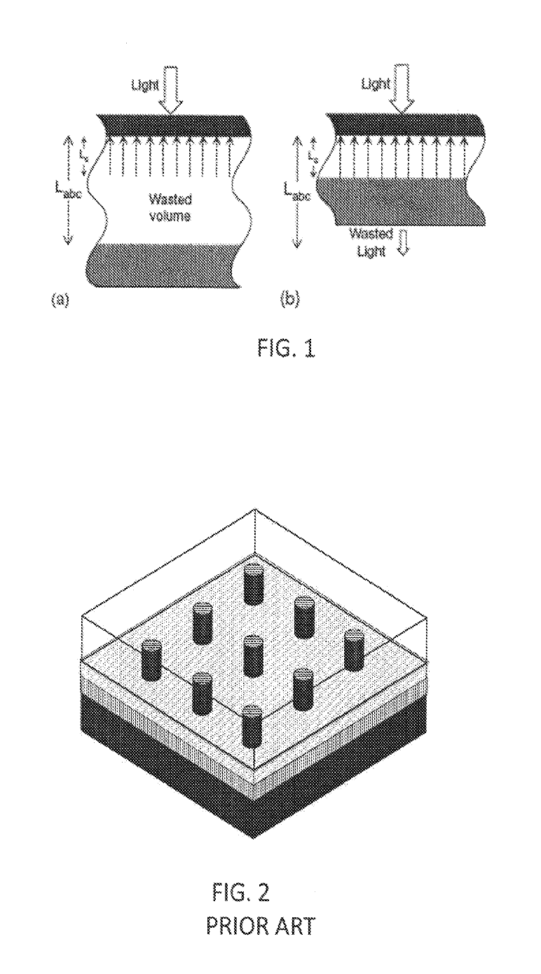

### DETAILED DESCRIPTION OF THE PREFERRED EMBODIMENTS

The present invention has utility as a light harvesting device for uses illustratively including photovoltaics, photolysis, and photodetection. The following description of the preferred embodiments is merely exemplary in nature and is in no way intended to limit the scope of the invention, its application, or uses, which may, of course, vary. The invention is described with relation to the non-limiting definitions and terminology included herein. These definitions and terminology are not designed to function as a limitation on the scope or practice of the invention but are presented for illustrative and descriptive purposes only.

An inventive Light and Carrier Collection Management (LCCM) device, photogenerated species (electrons and holes and/or excitons) collection from the full absorber volume and an advantageous distribution of the impinging light (photonic) energy within that volume are simultaneously attained using a design concept based on a repetitive structure referred to synonymously herein as a unit cell. The invention has utility for the conversion of light energy to electrical current.

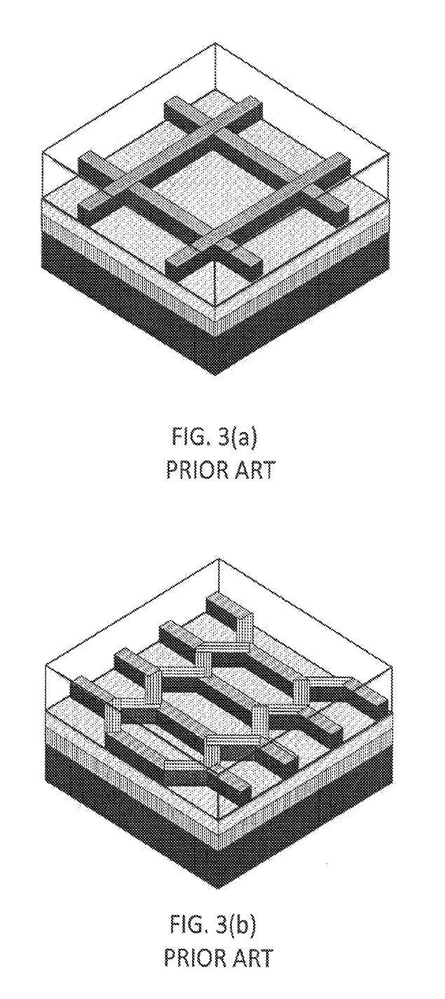

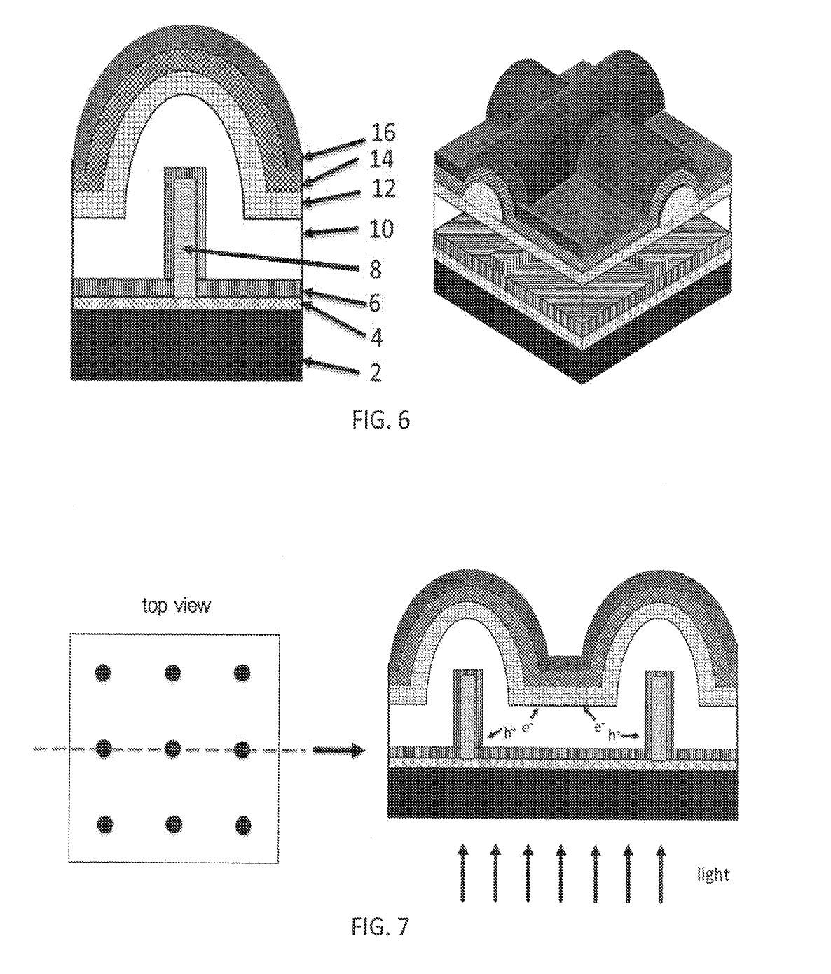

A unit cell of an inventive device is characterized by the distinctive feature of having an electrode element which penetrates into the absorber volume and which itself also defines that absorber volume. A cross- section and unit cell for a light and carrier collection management photovoltaic structure based on column-like element protrusions is seen in FIG. 5 while a cross- section and unit cell for an inventive device based on honeycomb-like element protrusion is seen in FIG. 6. In both examples, the absorber is material L. For a given absorber thickness and collection length, the inventive design has electrode elements that are of a composition, height and spacing that shape the absorber volume to enable photogenerated species to be essentially collected from more points within the absorber volume and preferably all points within the volume (See FIG. 7). Additionally an inventive design preferably simultaneously enables an essentially effective light (photon) energy distribution within the absorber volume, to permit the use of thinner absorber films for the same degree of absorption and (electron-hole and/or exciton) photogeneration as compared to conventional designs than would be expected based on the absorption length. The inventive device allows for the light distribution within the absorber volume to be set-up by some combination of optical path length (effective absorber thickness), reflection, photonic crystal-type wave interaction, and plasmonics. The unit cell of FIG. 5 may be of a pattern that covers an electrode of a photovoltaic device in a square or hexagonal lattice while the unit cell of FIG. 6 may be of a pattern that covers an electrode of a photovoltaic device in a square lattice. It is appreciated that in addition to the prior art configurations of FIGS. 2-4 being operative herein, other electrode shape arrays are operative herein.

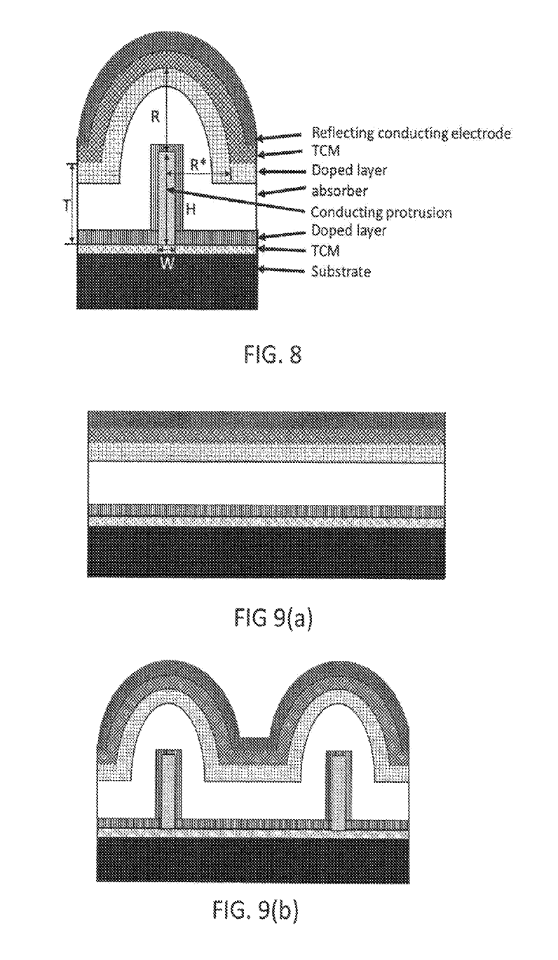

FIG. 8 shows the height H of the protruding elements which have a spacing L. These protrusions have a cross-section described by the parameter W. Since these protruding elements are part of an electrode, these protrusions are composed of conductors such as metals, doped semiconductors, and transparent materials such as transparent conducting oxides. It is appreciated that “protrusion” as used herein defines a generic three dimensional conducting or semiconducting feature with a unit cell extending between conductive layers such as transparent conductive materials (TCMs). When the absorber material is disposed on the positioned protruding electrode array, the absorber will form the absorber volume component among the protruding elements having a nominal thickness T (See FIG. 8) and form absorber volume component above the protruding elements as seen in FIGS. 5 and 6. While this volume component above the protruding elements is shown to be hemispherical in FIG. 5 and to have a circular cross-section in FIG. 6, the actual cross-sectional shape optionally varies depending on the absorber material and its thickness, and on the protruding material properties and characteristic lengths (H and W) and spacing L, as well as on the method of absorber deposition or growth. By way of example, the absorber shape is also conical, pyramidal, cuboidal, oblong, among other regular and irregular geometric forms. In any case, the cross-section of this absorber volume component is described herein by the parameter R seen in FIG. 8, which is defined as the largest linear dimension characterizing the absorber volume component crass-section above the protruding elements. The parameters H, W and L describing the electrode protrusions and their pattern (material D of FIGS. 5 and 6) together with the nominal thickness (thickness if deposited on a planar surface) of the deposited or grown absorber material film determine the overall absorber volume distribution, as may be seen from the cross section of the absorber (material E) in FIGS. 5 and 6. The electrode elements H, W and L are pattern together with the absorber film disposition approach and nominal thickness are chosen to result in an absorber volume distribution such that the majority, and preferably the all the points of the absorber volume are within a collection distance of the anode and cathode electrodes. Typical values of H, W and L are appreciated to depend on variables such as the intrinsic exciton diameter, carrier lifetime of the specific device, and carrier concentration. In general values of H, W and L are between 0.1 nm and 1 mm, 0.1 nm and 1 mm, and 0.1 nm and 5 mm; respectively.

To mitigate against the possibility of enhanced recombination (carrier) losses due to the large surface area of electrode material H in FIGS. 5 and 6, layer 14 is optionally introduced to create a contact selective to one carrier. In the example of FIG. 7, Layer 14 is an electron transport/hole blocking layer (ET/HBL) since electrode 16 has been taken to be the cathode. Electrode 16 is a low resistivity material. Since light enters through the bottom in FIG. 7, electrode 16 is optionally also a reflective material which happens to be the cathode in this example. In general values of H, W and L are between 0.1 nm and 1 mm, 0.1 nm and 1 mm, and 0.1 nm and 5 mm; respectively.

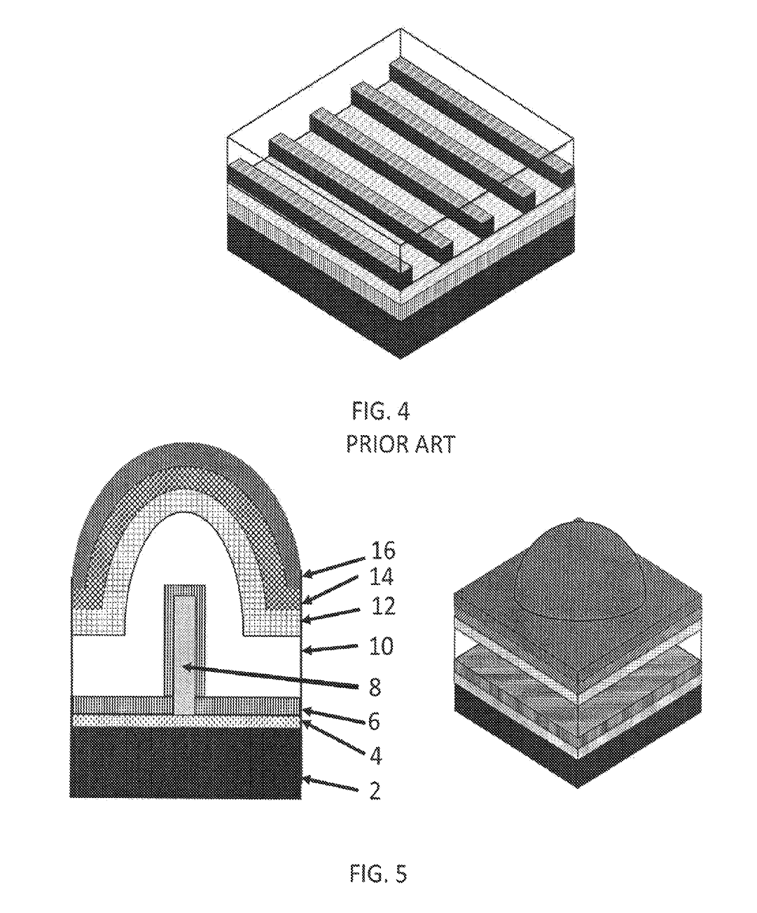

The parameters H, W and L (e.g., column diameter or honeycomb or fin width) and pattern of the protruding electrode elements (material D of FIGS. 4 and 5), the nominal thickness T of the deposited or grown absorber material film, and the composition of the protruding and counter electrodes are chosen to also result in a counter electrode configuration that produces a light (photon) energy distribution in the absorber which enhances photogeneration for a given absorber nominal thickness. This photon distribution is set-up by some combination of reflection, photonic, crystal-type wave interaction, and plasmonics caused also by the absorber volume and counter electrode configuration. The periodic absorber volume and counter electrode configuration, seen for example, in FIGS. 5 and 6, that is the product of the design of this invention is a photonic structure. When the protruding electrode elements are a metal or metal coated TCM, there can also result additional photon density modifications due to plasmonics and photonics effects. Representative TCMs illustratively include indium tin oxide and tin oxy-fluoride.

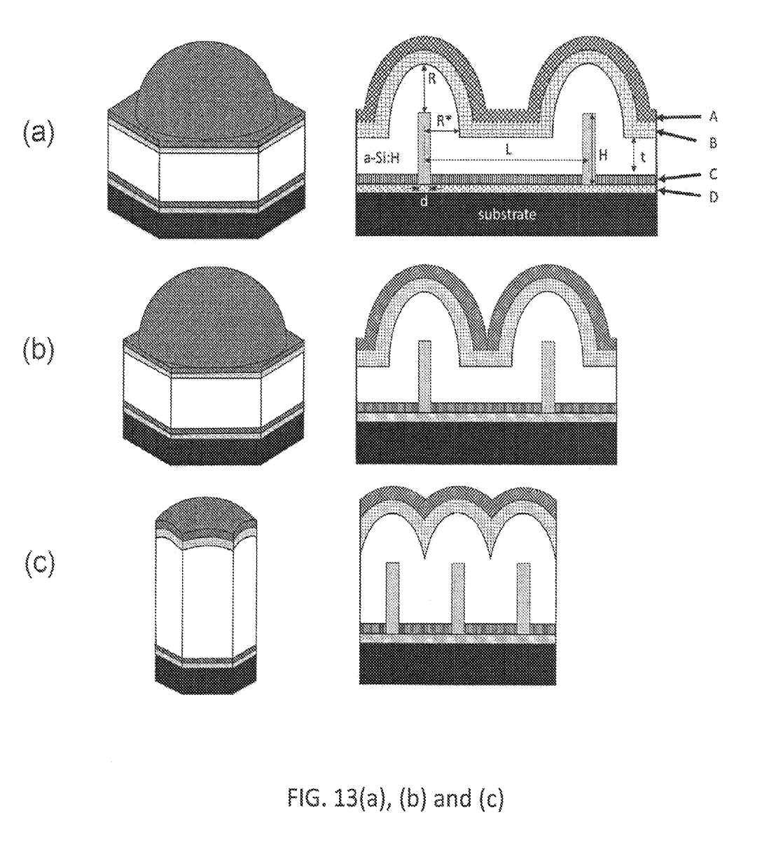

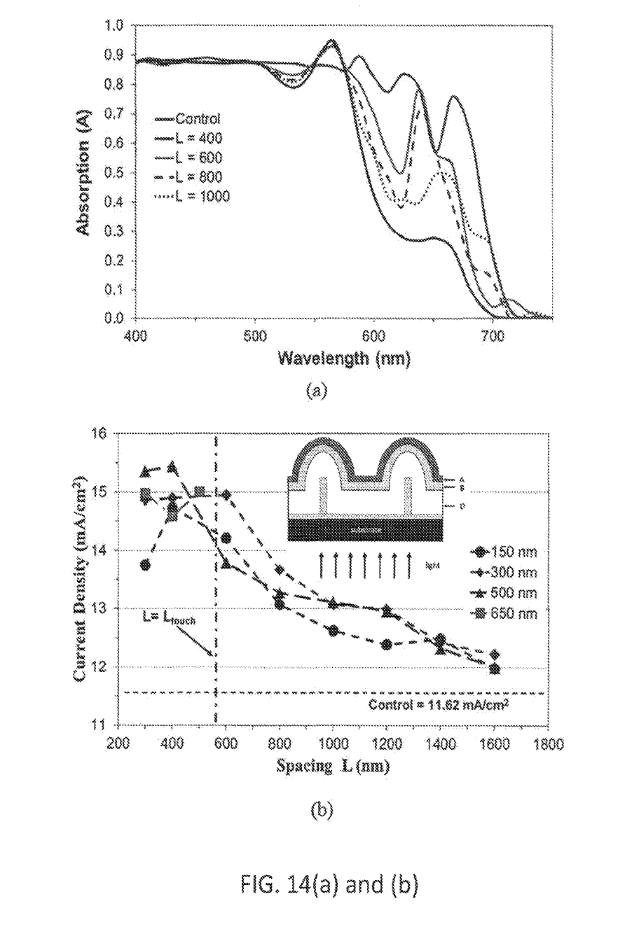

The structures of FIGS. 5-7 are usually termed superstrate solar cells; in that they have the light entering the cell through the mechanical support (layer A of these figures). It is appreciated that an inventive device is operative as either a superstrate cell mechanical support as shown in the accompanying figures, or through the substrate cell free surface. Table I provides some additional superstrate and substrate LCCM devices based on employing arrays of unit cell absorber protrusions. These may have various spacings L and the ramifications of this in terms of the truncation of the undulations is seen in FIGS. 13(a) and (b). Computer simulations comparing the performance of these four designs are presented in FIGS. 14-17. While the design concepts of this invention can be applied to any absorber and either drift or diffusion collection, these computer simulation results of FIG. 14-17 are for p-i-n junction a-Si:H devices. It is appreciated that other absorbers that may be used in actual devices include the III-V semiconductor family of materials (e.g., GaAs, InGaP, InGaAs), the broad chalcogenide family of materials (e.g., CdTe, CdSe, copper indium gallium arsenide), the group V family of materials (e.g., graphene, c-Si, polycrystalline Si, nanocrystalline Si and a-Si:H), organic absorbers (e.g., P3HT, dyes), and naturally occurring materials (e.g., iron pyrite). The concepts of this invention apply equally well to collection based on the full spectrum of junction types known to those in the field in addition to p-i-n junctions including homo- and heterojunctions as well as p-n, electrolyte, M-I-M and Schottky bather-type solar cell structures.

FIGS. 14(a) and (b) show the absorption A(λ) taking place in the a-Si:H absorber and J_{SC} performance for Configuration 1 of Table 1 which has the bottom light entry (superstrate cell), AZO nano-column elements, and Ag cathode described in Table 1. The A(λ) results of FIG. 14(a) include those of the planar p-i-n control and of Configuration 1 for H=500 nm for various L values. These plots show that A(λ) is much improved for the LCCM Configuration 1 devices compared to the respective control and has Fabry-Perot peak positions that is a function of L. The latter point demonstrates an influential role for the geometrical (photonic) scattering which changes as the domes evolve with L. A systematic trend is noted in FIG. 14(a) in which much of the long wavelength A(λ) response increases with decreasing L. This is caused by the redistribution of the absorber volume seen in FIGS. 13(a) and (b) as L changes; i.e., the trend is due to a longer optical pathlength per impingement area for decreasing L, which aids the weakly absorbed longer wavelengths. This longer optical pathlength per area is quantified with an effective absorber thickness defined by volume of a-Si:H divided by unit cell area; The effective absorber thickness increase with decreasing L also accounts for the J_{SC} trend with L seen in FIG. 14(b) for a fixed H value. The deviation from a strictly monotonic dependence of J_{SC} on L in these plots arises from the scattering behavior changes with L. Since the effective absorber thickness also increases with H, the existence of an optimum nano-element height, as seen in FIG. 14(b), also must be due to the scattering variations with H. As would be expected, J_{SC} is seen to approach the control value of 11.62 mA/cm² for larger L.

TABLE 1
Representative Inventive LCCM Device Designs

| Configuration # | | | | | |
|---|---|---|---|---|---|
| (Light entry | Nano-element** | | | | |
| direction) | (protrusion) | Layer A | Layer B | Layer C | Layer D |
| 1 | Shape = Cylider | (Cathode) | 5 nm | Not | (Anode) |
| (Bottom) | Material = AZO | Ag | AZO | present | 50 nm |
| | R = 220 nm, R* = | | | | AZO |
| | 220 nm | | | | |
| | d = 150 nm, H | | | | |
| | varies | | | | |
| 2 | Shape = Cylinder | (Anode) | Not | Not | (Cathode) |
| (Top) | Material = AZO | 80 nm | present | present | 5 nm or 30 nm |
| | R = 200 nm, R* = | AZO | | | AZO on Ag |
| | 150 nm | | | | |
| | d = 100 nm, H = | | | | |
| | 550 nm | | | | |
| 3 | Shape = Cylinder | (Anode) | Not | 5 nm or | (Cathode) |
| (Top) | Material = 5 nm | 80 nm | present | 30 nm | Ag |
| | AZO coated Ag | AZO | | AZO | |
| | film on SiO2 | | | between | |
| | R = 200 nm, R* = | | | columns | |
| | 150 nm | | | only | |
| | d = 90 nm, H = | | | | |
| | 550 nm | | | | |
| 4 | Shape = Cone | (Anode) | Not | Not | (Cathode) |
| (Top) | Material = AZO | 80 nm | present | present | 30 nm AZO |
| | R = 200 nm, R* = | AZO | | | on Ag |
| | 150 nm | | | | |
| | d = 100 nm | | | | |
| | H = 550 nm or | | | | |
| | 350 nm | | | | |

**The R and R* values used are in the range observed in conformal a-Si:H depositions on nano-element structures. These two parameters are used to better match the morphology and conformality of the absorber adjacent to and above the protrusion; i.e., R is now a vertical radius and R* is the horizontal radius describing the absorber.

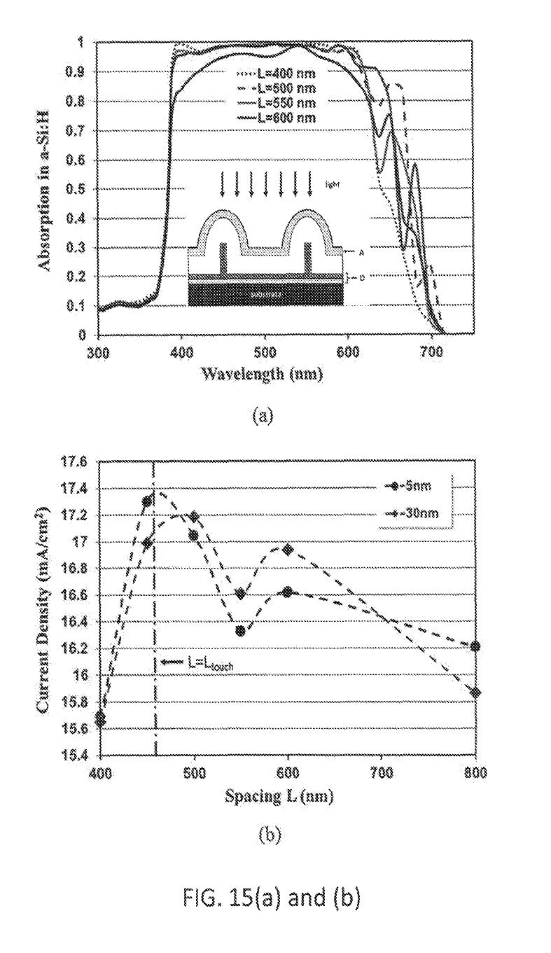

Configuration 2, also defined in Table 1, is a substrate-type of cell. It uses AZO columns as the nano-elements but has light entering through the top and, unlike Configuration 1, the AZO nano-columns now sit on a layer D composed of 30 nm of AZO coated onto an Ag opaque planar cathode. While ET/HBL layers can be use at the cathode, hole transport/electron blocking layers (HT/EBL) can also be used in general at the anode. FIG. 15(a) shows the resulting A(λ) behavior for when this AZO coating (D layer), functioning as an electron transport/hole blocking layer (ET/HBL) at the Ag cathode, is 30 nm thick. As seen, the A(λ) response is, in general, significantly improved over that of Configuration 1. It again displays a strong dependence on L, both in magnitude and in Fabry-Perot peak positions showing the importance of geometrical scattering. However, the long wavelength A(λ) behavior with increasing L is seen to be very different from that of Configuration 1. The repercussions of this are evident in FIG. 15(b) which gives two cases of J_{SC} as a function of L. Interestingly, the J_{SC} effective absorber thickness dependence, so dominant in Configuration 1, is seen to be unimportant in Configuration 2 whereas geometrical scattering is now quite important. In particular, J_{SC} decreases with decreasing L for L<L_{touch}, it has two relative maxima in the range L>L_{touch}, and has an absolute maximum near L˜L_{touch}. The latter suggests scattering within the domes, as opposed to among domes, is paramount. The highest J_{SC} is ˜15.4 mA/cm² for Configuration 1 whereas it is at least 17.3 mA/cm² for Configuration 2, a ˜49% increase in J_{SC} over that of the control.

The two J_{SC} plots in FIG. 15(b) point out the sensitivity of the A(λ) behavior to the details of device layer thicknesses and composition. Detailed examination shows that both geometrical scattering and plasmonic scattering differences play a role through changes in the long wavelength A(λ) behavior. The former is seen through shifts in the Fabry-Perot absorption peaks with D layer AZO thickness and the latter is seen in the significant reduction in the long wavelength absorption which occurs for the 5 nm case when Ag is replaced by Al in the modeling (not plotted). This suggests that the thinner AZO D layer case, which still has AZO that is thick enough to block hole tunneling at the cathode, allows the enhanced near-field at the Ag surface to penetrate the absorber more deeply.

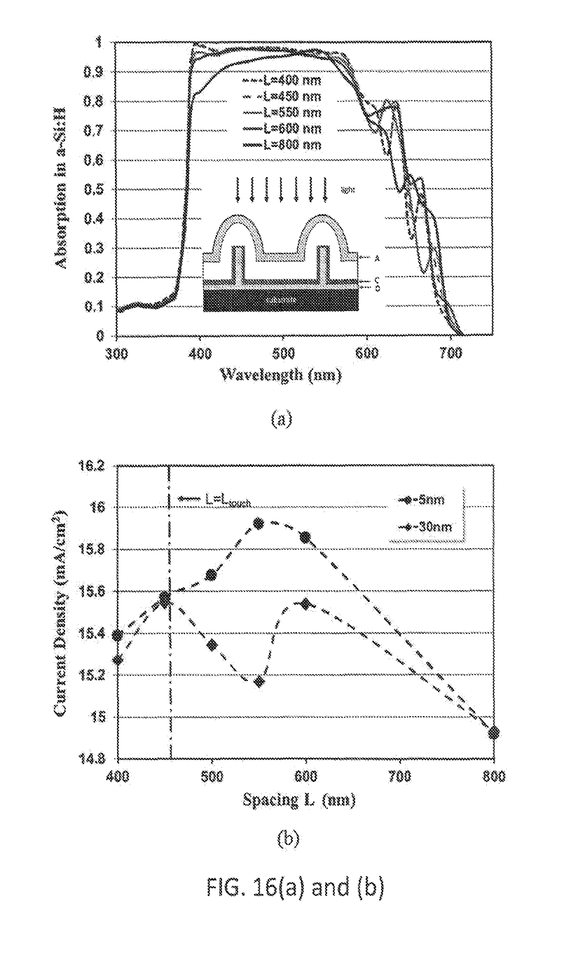

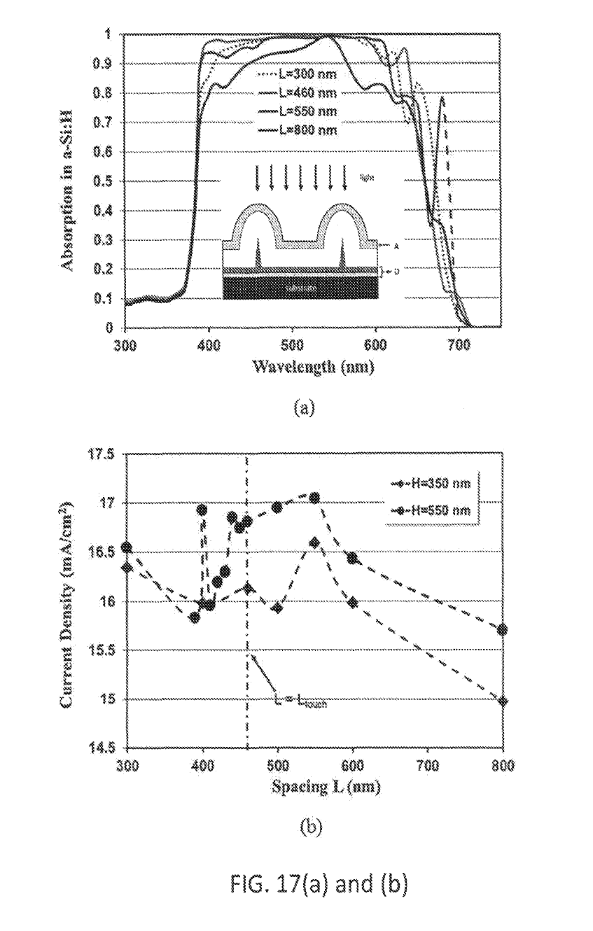

In the Configuration 3 architecture, also a substrate cell, the nano-columns are now composed of 5 nm AZO (ET/HBL) film on an Ag coated SiO₂ core. Each of these nano-columns sits on a planar Ag (layer D) cathode and, between the nano-columns, there is a layer C, which is also an AZO ET/HBL, residing on the planar Ag. FIG. 16a shows that the resulting A(λ) plots for Configuration 3 are inferior to those of Configuration 2 in the middle wavelengths but even more so in the longer wavelengths. The impact of this poorer A(λ) performance on J_{SC} is displayed in FIG. 16b for two layer C thicknesses. Once again a thinner AZO layer on the planar Ag cathode is seen to improve performance. While the J_{SC} curves of FIG. 16b display an overall dependence on L which is similar to that of FIG. 15b, there are peaks present for the 30 nm but not for the 5 nm C layer. This points out that there is a significant difference in the geometrical scattering interaction taking place in the Ag coated nano-column/5 nm coated Ag planar cathode situation versus that taking place in the Ag coated nano-column/30 nm coated Ag planar cathode situation. There is also plasmonic scattering influence involved in the thinner C layer case since replacing Ag with Al in the modeling reduces the long wavelength A(λ) response (not plotted). Interestingly, the fact that the peak in J_{SC} clearly occurs for L>L_{touch}. shows the dominance of scattering interactions among domes that can clearly occur in some architectures.

Configuration 4 of Table I is the same as Configuration 2 except it has AZO cone-shaped nano-elements. As is the case for Configuration 2, these nano-elements are positioned on a layer D composed of 30 nm of AZO on planar Ag. FIG. 17a shows the A(λ) dependence on L for this architecture for H=550 nm.. The variation in the magnitude and Fabry-Perot peak positions of A(λ) with L demonstrate the importance of the geometrical scattering taking place. FIG. 17b presents J_{SC} as a function of L for H=350 and H=550 nm. As seen, the dependence of the J_{SC} maximum on H again underscores the importance of the choice of nano-element height in these architectures. The behavior of the J_{SC} curves with L is essentially that of FIGS. 15b and 16b for L>L_{touch}. Interestingly, the short L behavior is very different from that seen for Configurations 2 and 3. With the exception of the resonance-like J_{SC} peak at L=400 nm for H=550 nm, the small spacing behavior is much more like that present for Configuration 1. This suggests a dominating role for effective absorber thickness dependence, in this L regime. The origin of this dependence may arise from the increasing importance of the extra absorber volume with decreasing L coming from the tapering of the nano-cones. Configuration 4 is similar to that discussed in J. Zhu, C. M. Hsu, Z. Yu, S. Fan, and Y. Cui, Nano Lett., 2010,10, 1979. except the structure of that reference has an Ag coating over the nano-cones. If the A(λ) results of that work are used to obtain J_{SC} but the computation is limited to photon energies≧the band gap of a-Si:H, then a J_{SC} of 17.43 mA/cm² is obtained. This is comparable to that seen for Configuration 4 but is an overestimation since the Ag absorption for λ<700 nm, included in J. Zhu, C. M. Hsu, Z. Yu, S. Fan, and Y. Cui, Nano Lett., 2010,10, 1979 has not been removed.

The designs Table I and FIGS. 13-15 establish that there are four effects in a nano-element based architecture which can impact the J_{SC} potentially available, and therefore the PCE, in single junction a-Si:H LCCM devices: intra- and inter-dome geometrical scattering, plasmonic scattering, and effective absorption length effects. These are in addition to standard reflection. The advantageous architectures are shown to be those that rely on geometrical scattering augmented by plasmonic scattering. Optimized a-Si:H versions of such structures, using a 200 nm a-Si:H deposition, are shown to be capable of J_{SC} values which are at least 49% better than that of the corresponding control structure. The modeling shows that nano-columns and nano-cones—and presumably anything in between including columns with rounded tops—will function equally well.

The simulations also show that nano-element spacings in the ˜½ miron range can be ideal. Both of these results make manufacturing the nano-element array considerably easier than might be expected and point to the use of high through-put nano-imprinting for fabrication. Such imprinting can be done in a roll-to-roll format.

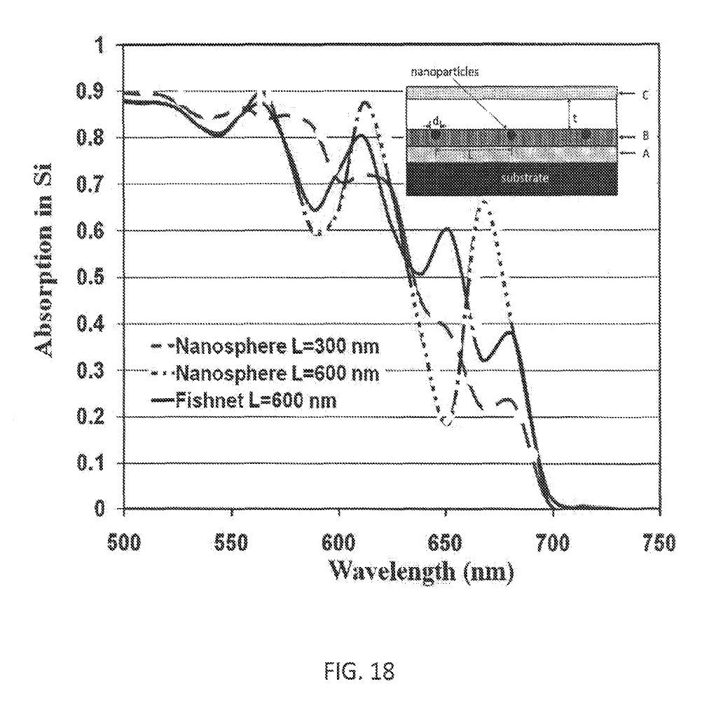

FIG. 18 are absorption spectra for an embodiment of the present invention in which nanospheres or a nanowire fishnet serve as the protrusions with the L spacing of 300 nm or 600 nm. The ability of nanospheres or a two-dimensional nanowire fishnet to imporove the light harvesting efficiency of the device are shown. The figure inset is a cross-sectional schematic of the device, where the nanoparticles function as the protruding electrode element material noted with respect to FIG. 5 as reference numeral 8, the material noted at reference A is transparent conducting material noted with respect to FIG. 5 as reference numeral 4 is a transparent insulative material, the material noted at reference B is a matrix material, the material noted at reference C is counter electrode material noted with respect to FIG. 5 as reference numeral 16. The dimensions t and d denote the thickness of the absorber layer and the minimal linear extent of the nano-element, respectively.

Various aspects of the present invention are illustrated by the following non-limiting examples. The examples are for illustrative purposes and are not a limitation on any practice of the present invention. It will be understood that variations and modifications can be made without departing from the spirit and scope of the invention.

### EXAMPLES

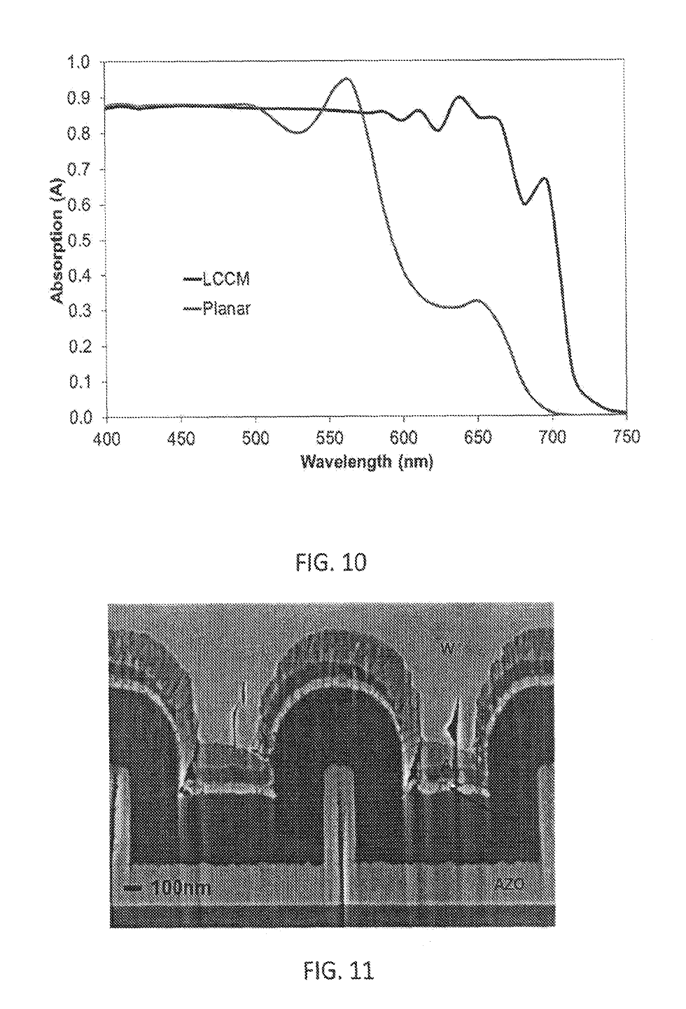

The results of mathematically determining, using a Maxwell's equations solver, the absorption produced in a conventional (planar) device (FIG. 9(a)) and in a corresponding light and carrier collection management (LCCM) device (of the type of FIG. 5) with the same nominal thickness absorber layer (FIG. 9(b)) are given in FIG. 10. In these embodiments, material A is glass (through which the light is entering), material B is a transparent conducting material upon which the protruding elements reside, material C is P+a Si:H, material D is the protruding columnar electrode element material assumed to be P+a-Si;H, material E is an intrinsic a-Sl:H absorber, material F is N+a-Si:H, material G is an ET/HBL material, and material H is the counter electrode material selected to be Ag in this case. The results shown in FIG. 10 are actually the result of working to design an optimized LCCM design. (V. V, Varadan, et al., the 35^{th} IEEE PVSC proceedings). This design resulting from the computer simulation gives, for a nominal intrinsic a-Si:H absorber thickness of 400 nm and a collection length of 400 nm, the following design values: R=160 nm, L=800 nm, and H=160 nm. This structure is seen in FIG. 10 provides advantageous photon distribution in the absorber thereby producing enhanced absorption behavior and simultaneously allows harvesting from every point in the absorber volume. A collection length in a-Si:H of 400 nm is used since this value is experimentally known to be realistic (and determined by holes) in a p-i-n cell. As seen in FIG. 10, the LCCM design for this absorber nominal thickness chosen and R, W, H, and T values used give better absorption at the short wavelengths than that seen for the convention cell but, more importantly, give substantial absorption enhancement at the long wavelengths. These long wavelength photons are difficult to absorb in a conventional cell and their absorption in conventional cells necessitates thicker absorber materials. The LCCM design gives stronger absorption in thinner absorbers while allowing collection to be possible from every point in the absorber volume.

LCCM devices with various protruding electrode materials have been fabricated guided by the design rules of this invention. Electrode protrusions have been fabricated using e-beam lithography to create a hard mask defining where the electrode element will reside and defining its dimensions followed by reactive ion etching (RIE) to create the protrusion elements by etching a deposited or grown material. This material (metal, TCM, or semiconductor) then becomes the protrusion element by RIE. Electrode protrusions have also been fabricated using e-beam lithography and reactive ion etching (R1E) to create a template containing empty regions into which the electrode element material is deposited or grown. Techniques for this disposition include a variety of methodologies such as atomic layer deposition (ALD) and electro-chemical growth. While the lithography step used in these embodiments has been predominantly e-beam lithography, block co-polymer lithography has also been used to successfully produce protruding electrode elements. In a production application of the design approach of this invention, a number of lithography techniques may be utilized to define the protruding electrode pattern shape and spacing an element dimensions including block co-polymer lithography and imprint lithography, among others. After the definition and fabrication of the protruding electrode elements which reside on a conductor (FIGS. 5 and 6) on glass or other substrate material, such as plastic or ceramic, the absorber is deposited or grown. This may be preceded or followed by the positioning of a doping layer. This deposition's or growth's nominal thickness together with H, T, and L determine R and the distribution of the absorber volume components. After the completion of the absorber, a selective contact material may be disposed followed by the addition of a conducting layer. Optionally, the conducting layer is a reflector.

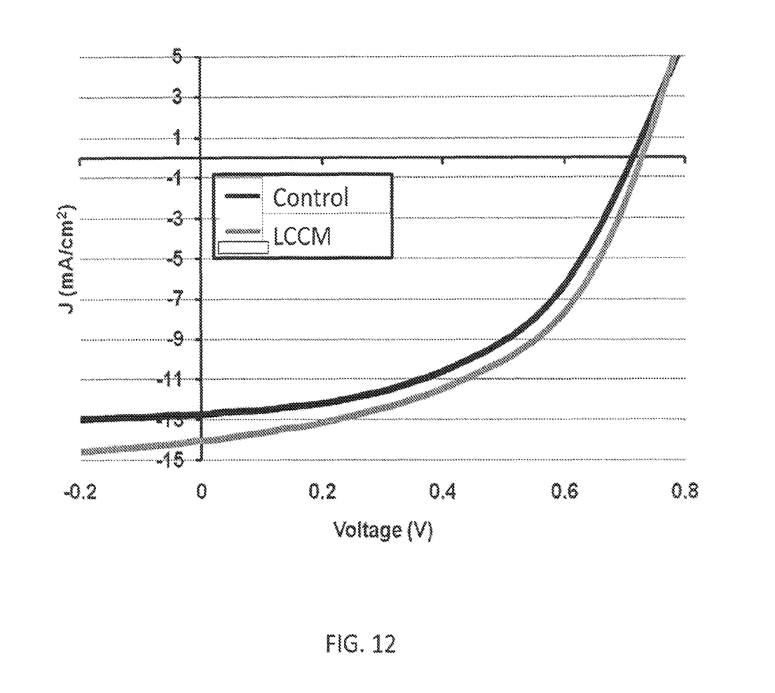

FIG. 11 shows such an LCCM device after fabrication. In this case, the various dimension were, however, not fully optimized for the nominal thickness and collection length of the absorber used (intrinsic a Si:H), In this particular example, the Si;H absorber has embedded aluminum doped zinc oxide (AZO) nano-scale columnar electrode structures whose dimensions are about W=100 nm (diameter) and H=400 nm. They have a spacing L=800 nm. In the case of these AZO electrode devices, the nanostructure is fabricated by using electron beam lithography (EBL). In brief, the structure fabrication steps begin with coatings of a polymer layer (LORSa) followed by a silicon nitride layer on a TCM coaled glass substrate. After coating of these layers, the nano-scale pattern was defined on them. The defined pattern was transferred to the two layers during the following dry etching steps (O₂ plasma and CF₄/O₂ plasma), thereby forming empty regions in the coating layers. These were filled by atomic layer deposited (ALD) aluminum Zinc oxide (AZO) material. The film not only filled the empty regions but also blanket deposited across the top coating. The AZO electrode structures were obtained when the top blanket AZO layer and the two codling layers (the polymer layer and the silicon nitride layer defining what was the empty regions) were removed during a subsequent dry etching step (BCI₃ plasma/O₂ plasma). After the steps defining the electrode protrusion elements, a 20 nm thick n+−a-Si;H layer, a 400 nm thick intrinsic a Si:H layer, and a 20 nm thick n+a-Si:H layer were deposited in one sequence, without breaking vacuum, by plasma enhanced chemical vapor deposition vapor deposition (PECVD). FIG. 12 gives an indication of the impact that the LCCM structure can have on solar cell performance. FIG. 12 shows the efficiency of a LCCM device compared to a corresponding conventional planar device made with the same absorber and nominal absorber thickness. The efficiency of the LCCM device is 45% higher than that of the conventional planar device.

Reagents and materials used, are commercially available or synthesizable by one of ordinary skill in the art using conventional techniques without undue experimentation, and a person of ordinary skill in the art readily understands where such reagents may be obtained.

Various modifications of the present invention, in addition to those shown and described herein, will be apparent to those—skilled in the art of the above description. Such modifications are also intended to fall within the scope of the appended claims,

Patents and publications mentioned in the specification are indicative of the levels of those skilled in the art to which the invention pertains. These patents and publications are incorporated herein by reference to the same extent as if each individual application or publication was specifically individually incorporated herein by reference,

The foregoing description is illustrative of particular embodiments of the invention, but is not meant to be a limitation upon the practice thereof The following claims, including ail equivalents thereof, are intended to define the scope of the invention.

1. A photovoltaic device comprising:
a periodic array having a unit cell with a first electrode protrusion having a height H, characteristic width W, and period L;
an absorber of nominal thickness T wherein said absorber has a volume with a first component between the electrode protrusion and a second component completely covering said electrode element protrusions, wherein H, W, and L for a given T allow carrier collection from a majority of points within the volume and simultaneously to enhance the photon density distribution within the absorber resulting from path length, photonic and plasmonic effects produced by the topology and morphology created by said first electrode and a volume distribution between the first and the second components.

2. A photovoltaic device comprising:
a first electrode with protrusions having repeating spacing L arranged in a square or hexagonal lattice and having a height H; an absorber having a nominal thickness

3. A photovoltaic cell comprising:
a first electrode have nano-element protrusions with repeating spacing L positioned in an array, said nano-elements having a light absorber material disposed between the elements, on the element sides, and over the elements, said absorbing material optionally having, or being located between, junction-forming layers and optionally having, or being located between, transport/blocking layers, said photovoltaic cell having a counter-electrode.

4. The cell claim 1 wherein the first electrode is the anode.

5. The cell of claim 1 wherein the first electrode is the cathode.

6. The cell of claim 1 wherein light enters the device through a transparent cathode and the anode is reflective.

7. The cell of claim 1 wherein light enters the device through a transparent anode and the cathode is reflective.

8. The cell of claim 1 further comprising a transport/blocking layer between said absorber and one or both of said first electrode and a second electrode.

9. The cell of claim 1 wherein the protrusions have a longest linear dimension from the first electrode of between 5 and 1000 nm.

10. The cell of claim 1 wherein the protrusions have the repeat spacing of between 10 and 1000 nm.

11. The cell of claim 1 wherein the protrusions are nanospheres or a nanowire fishnet.
